(19) United States
(12) Patent Application Publication
(10) Pub. No.: US 2004/0241918 A1
(43) Pub. Date: Dec. 2, 2004

(54) Method for making thin-film semiconductor device, thin-film semiconductor device, method for making electro-optic apparatus, electro-optic apparatus, and electronic apparatuses

(75) Inventor: Hiroshi Sera, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/826,366

(22) Filed: Apr. 19, 2004

(30) Foreign Application Priority Data
Apr. 25, 2003 (JP) 2003-121673
Jan. 22, 2004 (JP) 2004-014920

(51) Int. Cl. H01L 21/00; H01L 21/8249

(52) U.S. Cl. 438/151; 438/163

(57) ABSTRACT

The invention provides a method for making a thin-film semiconductor device for accurately controlling the LDD length regardless of the structure or the LDD length of a gate electrode. First, on a substrate, a semiconductor film with a predetermined pattern, a gate-insulating film, and a tapered gate electrode can be disposed in sequence. Then a low concentration of impurity can be implanted into the semiconductor film through the gate electrode functioning as a mask. Then, after a layered insulating film composed of at least two different insulating films is disposed on the gate electrode on the transmissive substrate, the entire surface is etched to form a layered insulating film with a predetermined pattern so that at least one layer of the insulating film has a width greater than the gate electrode and smaller than the semiconductor film. Subsequently, a high concentration of impurity can be implanted into the semiconductor film through the layered insulating film functioning as a mask.

### BACKGROUND OF THE INVENTION

1. Field of Invention

The invention relates to a thin-film semiconductor device, a method for making the thin-film semiconductor device, an electro-optic apparatus, a method for making the electro-optic apparatus, and electronic apparatuses. More specifically, the invention relates to technologies concerning the production of a thin-film semiconductor device having a lightly doped drain (LDD) structure.

2. Description of Related Art

In the art there are known electro-optic apparatuses, such as liquid crystal apparatuses, electro-luminescence (EL) apparatuses, and plasma displays. Such electro-optic apparatuses are active-matrix electro-optic apparatuses having thin-film transistors (TFT), which are thin-film semiconductor devices, each disposed on dots arranged in a matrix for driving the dots independently. A known TFT used for this purpose has an LDD structure in which a region with a relatively high impurity concentration and a region with a relatively low impurity concentration function as a source region and a drain region, respectively. It is important to accurately control the LDD length (i.e., the width of the low concentration region) in a TFT having an LDD structure.

In the technical field related to semiconductor devices, such as an integrated circuit (IC), technology is known for controlling the LDD length by forming a sidewall on a gate electrode. See, for example, Japanese Unexamined Patent Application Publication No. 5-136163, Japanese Unexamined Patent Application Publication No. 8-125178, and Japanese Unexamined Patent Application Publication No. 11-68090.

This technology is briefly explained by describing a case in which an n-channel MOS transistor is produced.

First, as shown in FIG. 10(A), a p-well 210 is disposed on a silicon wafer 200. On the silicon wafer 200, a gate-insulating film 201 having a predetermined pattern is deposited and, then, a metal gate electrode 202 is deposited. Next, by using the gate electrode 202 as a mask, a low concentration of n-type impurity ions 300 is implanted to form a source region 203 and a drain region 204 having low concentrations.

In this way, as shown in FIG. 10(B), an insulating layer 205 is formed on the entire surface of the silicon wafer 200. Then, as shown in FIG. 10(C), sidewalls 205a are formed by etching back the insulating layer 205 to leave the insulating layer 205 only on the sides of the gate-insulating film 201 and the gate electrode 202. Finally, as shown in FIG. 10(D), by using the gate electrode 202 and the sidewalls 205a as a mask, a high concentration of n-type impurity ions 301 is implanted at the source region 203 and the drain region 204 to form high concentration regions 203b and 204b while low concentration regions 203a and 204a remain directly below the sidewalls 205a.

In this way, the sidewalls 205a are formed on the gate-insulating film 201 and the gate electrode 202 with a width substantially the same as the thickness of the insulating layer 205 disposed on the entire surface of the silicon wafer 200. Then, the low concentration regions (LDD regions) 203a and 204a are formed with a thickness substantially the same as the width of the sidewalls 205a. Consequently, the LDD length can be controlled according to the film thickness of the insulating layer 205. Thus, the LDD length can be controlled accurately.

### SUMMARY OF THE INVENTION

As described below, it is extremely difficult to apply the above-mentioned technology, which belongs to the technical field related to semiconductor devices, such as an IC, to the technical field related to electro-optic apparatuses. Thus, under the present circumstances, such technology has not yet been brought into practical application.

In a semiconductor device, such as an IC, the sides of the gate electrode are substantially perpendicular to the surface of the gate-insulating film. Therefore, the sidewalls can be formed by etching back the insulating layer so that it remains on the sides of the gate electrode.

For a semiconductor device, such as an IC, the transistor requires a gate electrode with a film thickness of only about 0.3 μm and an LDD length of about 0.2 μm. On the other hand, for an electro-optic apparatus, the transistor must be a TFT having a larger size in which the film thickness of the gate electrode is about 0.3 to 0.8 μm and the LDD length is about 0.5 to 1.0 μm. Consequently, it is difficult to form substantially perpendicular sides for the gate electrode. Even if it is possible to form substantially perpendicular sides for the gate electrode, it is difficult to dispose an interlayer insulating film on the sides of the gate electrode. For this reason, there is a possibility of data lines and source lines breaking. To prevent this, in general, the gate electrode of an electro-optic apparatus is tapered at a 20 to 80° angle.

When a tapered gate electrode is formed, sidewalls cannot be formed because when an insulating layer is disposed on the entire surface of a gate electrode disposed on a substrate and is etched back, the entire insulating layer will be etched off. Even if it is possible to form substantially perpendicular sides for the gate electrode, with the known technology related to semiconductor devices, such as an IC, the thickness of the insulating layer becomes substantially equal to the LDD length. Therefore, in order to achieve an LDD length of about 0.5 to 1 μm, an insulating layer with a thickness of about 1 μm must be formed. It is, however, extremely difficult to form an insulating layer with a large, uniform thickness of 1 μm. It is also extremely difficult to accurately etch the insulating layer and accurately form sidewalls having a predetermined structure.

Taking these problems into consideration, the object of the invention is to provide means for achieving an accurate LDD length of approximately 0.5 to 1 μm regardless of the structure of the sides of the gate electrode.

In the method for making a thin-film semiconductor device having a semiconductor film which has a source region, a channel region, and a drain region, and a gate electrode opposing the semiconductor film with a gate-insulating film interposed therebetween, the source region and the drain region being formed of a high concentration region having a relatively high impurity concentration and a low concentration region having a relatively low impurity concentration, respectively, the method can include the steps of forming a semiconductor film having a predetermined pattern on a substrate, forming a gate-insulating film on the semiconductor film, forming a tapered gate electrode on the gate-insulating film, implanting a low concentration of impurity into the semiconductor film through the gate electrode functioning as a mask, forming a layered insulating film composed of two or more different insulating films on the gate electrode, forming a predetermined pattern in at least one layer of the insulating film by etching the entire surface of the layered insulating film so that the width of the layered insulating film is greater than the width of the gate electrode and smaller than the width of the semiconductor film, and implanting a high concentration of impurity into the semiconductor film through the layered insulating film having a predetermined pattern functioning as a mask.

In other words, the method for making a thin-film semiconductor device according to the invention can include the following characteristics: (1) after a tapered gate electrode is formed, low concentration source and drain regions are formed on the semiconductor film by implanting a low concentration of impurity into the semiconductor film through the gate electrode functioning as a mask; (2) after the low concentration source and drain regions are formed on the semiconductor film, a layered insulating film having at least two layers composed of at least two different insulating films is formed on the gate electrode disposed on the substrate; (3) by etching the entire surface of the layered insulating film, an insulating film having at least one layer is formed with a width greater than the width of the gate electrode and smaller than the width of the semiconductor film; and (4) low concentration regions are left directly below the source and drain regions of the insulating film while high concentration regions are formed in the portions not directly below the source and drain regions by implanting a high concentration of impurity into the semiconductor film through the insulating film having a predetermined shape functioning as a mask.

In the method for making a thin-film semiconductor device according to the invention, after the low concentration source and drain regions are formed on the semiconductor film, an insulating film having a predetermined pattern with a width greater than the width of the gate electrode and smaller than the width of the semiconductor film is disposed on the gate electrode on the substrate. Then, the high concentration of impurity is implanted into the semiconductor film through the insulating film functioning as a mask. In this way, the length of portions of the source and drain regions with a width greater than the width of the gate electrode on the insulating film having a predetermined shape is equal to the LDD length. Thus, the LDD length can be accurately controlled.

In the invention, the insulating film used as the mask can be formed of a layered insulating film composed of two or more different insulating films. Therefore, by controlling the conditions of layering such as the type of insulating film, the thickness of the film, and the structure of the layers and the conditions of the etching performed on the insulating film, the structure of the insulating film can be controlled, and, consequently, the LDD length can be controlled.

In particular, to form the layered insulating film so that it has a predetermined shape with a width greater than the width of the gate electrode and smaller than the width of the semiconductor film, for example, a first insulating film different from the gate-insulating film can be formed and then, a second insulating film different from the first insulating film is formed. Then the entire surface of the insulating films can be etched so that the etching rate of the first insulating film contacting the gate-insulating film is smaller than the etching rate of the second insulating film.

Similarly, through the process of forming a predetermined pattern on the layered insulating film, the layered insulating film may be structured with a width greater than the width of the gate electrode and smaller than the width of the semiconductor film by anisotropically etching the layered insulating film after at least one layer of the layered insulating film is formed according to the predetermined pattern with a width is greater than the width of the gate electrode and smaller than the width of the semiconductor film.

According to the method for making a thin-film semiconductor device according to the invention, the LDD length can be controlled based on a plurality of conditions such as the thickness, type, and layer structure of the insulating film and the etching conditions. In this way, a required LDD length corresponding to the tapered gate electrode can be obtained. In the thin-film semiconductor device, unlike an IC element, a gate-insulating film is disposed on the LDD regions. According to the invention, by stacking two or more different insulating films, the required thickness of the gate-insulating film may be maintained even after the entire surface is etched. Therefore, for example, by forming the first insulating film, which differs from the gate-insulating film disposed on the tapered gate electrode, on the gate-insulating film and by forming the second insulating film, which differs from the first insulating film, on the first insulating film and, then, by etching the entire surface of the insulating films, the LDD length can be controlled without excessively etching the gate-insulating film.

The structure of the layered insulating film can be controlled by controlling the etching conditions, the film structure, the film thickness, and the number of film layers. Consequently, in various conditions, the layered insulating film can be structured so as to have a predetermined pattern with a width greater than the width of the gate electrode and smaller than the width of the semiconductor film.

In the method for making a thin-film semiconductor device according to the invention, the uppermost layer of the layered insulating film can be formed isotropically during the process of forming the layered insulating film. Subsequently, the entire layered insulating film can be anisotropically etched in the process of etching the layered insulating film. In this way, advantages of the invention are assured.

In the method for making a thin-film semiconductor device according to the invention, the primary composition of the uppermost insulating film and the gate-insulating film may be the same.

In the etching process of the layered insulating film in the method for making a thin-film semiconductor device according to the invention, the volume of the insulating film remaining in the vicinity of the gate electrode can be controlled by detecting the endpoint of etching for the uppermost insulating film of the layered insulating film. In this way, the final LDD length can be easily controlled.

In the etching process of the layered insulating film in the method for making a thin-film semiconductor device according to the invention, the rate of the etching performed on the upper insulating film may be greater than the rate of the etching performed on the lower insulating film, and the rate of the etching performed on the exposed lower insulating film may be greater than the rate of etching performed on the upper insulating film. In this way, the insulating film remains along the gate electrode with a greater width compared to when a single-layered insulating film is used.

In the method for making a thin-film semiconductor device according to the invention, the gate-insulating film may be composed of, for example, silicon oxide. Moreover, the layered insulating film may have a first insulating film composed of silicon oxide and a second insulating film composed of silicon nitride stacked on the first insulating film.

The method for making a thin-film semiconductor device according to the invention is especially effective for producing a thin-film semiconductor device having a tapered gate electrode or a thin-film semiconductor device requiring a large LDD length of about 0.5 to 1 μm for which sidewalls cannot be formed by employing the known technology in which the single-layered insulating film is etched back to control the LDD length. In this specification, the term width refers to the length in the longitudinal direction of the LDD.

The thin-film semiconductor device according to the invention is produced in accordance with the method for making a thin-film semiconductor device according to the invention. The thin-film semiconductor device has a layered insulating film disposed along at least the upper surface and the sides of the gate electrode. The source and drain regions of the semiconductor film have a low concentration region corresponding to the portions of the insulating film with a width greater than the gate electrode.

Since the thin-film semiconductor device according to the invention is produced in accordance with the method for making a thin-film semiconductor device according to the invention, the LDD length can be accurately controlled regardless of the structure of the sides of the gate electrode and the LDD length. Thus, the performance of the thin-film semiconductor device including durability and current-voltage characteristics becomes excellent.

The method for making a thin-film semiconductor device according to the invention is especially effective for producing an electro-optic apparatus requiring a relatively large-scale thin-film semiconductor device compared to a semiconductor device such as an IC.

The method for making an electro-optic apparatus according to the invention can include making a thin-film semiconductor device having a semiconductor film with a source region, a channel region, and a drain region and a gate electrode opposing the semiconductor film with a gate-insulating film interposed therebetween, the source region and the drain region can be formed of a high concentration region having a relatively high impurity concentration and a low concentration region having a relatively low impurity concentration, respectively. The method can include the steps of forming a semiconductor film with a predetermined pattern on a substrate, forming a gate-insulating film on the semiconductor film, forming a tapered gate electrode on the gate-insulating film, implanting a low concentration of impurity into the semiconductor film through the gate electrode functioning as a mask, forming a layered insulating film composed of two or more layers of at least two different insulating films on the gate electrode, forming a predetermined pattern in at least one layer of the insulating film by etching the entire surface of the layered insulating film so that the width of the layered insulating film is greater than the width of the gate electrode and smaller than the width of the semiconductor film, and implanting a high concentration of impurity into the semiconductor film through the layered insulating film with a predetermined pattern functioning as a mask.

A method for making an electro-optic apparatus according to the invention has been developed by applying the method for making a thin-film semiconductor device according to the invention to an electro-optic apparatus. Therefore, according to the method for making the electro-optic apparatus according to the invention, when a thin-film semiconductor device is produced, the LDD length can be controlled accurately regardless of the structure of the sides of the gate electrode and the LDD length.

The electro-optic apparatus according to the invention can be produced by the method for making the electro-optic apparatus according to the invention. An insulating film of the electro-optic apparatus is disposed along at least the upper surface and sides of a tapered gate electrode. Also, in a source region and a drain region of a semiconductor film of the electro-optical apparatus, a low concentration region corresponding to portions of the insulating film is formed with a width greater than the gate electrode.

The electro-optic apparatus according to the invention is produced in accordance with the method for producing an electro-optic apparatus according to the invention. Therefore, the LDD length can be controlled accurately regardless of the structure of the sides of the gate electrode and the LDD length, and, as a result, the performance of the thin-film semiconductor device becomes excellent.

By including an electro-optical apparatus according to the invention in an electronic apparatus, an electro-optic apparatus with excellent performance can be provided.

### BRIEF DESCRIPTION OF THE DRAWINGS

The invention will be described with reference to the accompanying drawings, wherein like numerals reference like elements, and wherein:

FIG. 1 is an equivalent circuit diagram of switching elements and signal lines for a plurality of dots arranged in a matrix constituting an image display area of a liquid crystal apparatus according to an embodiment of the invention;

FIG. 2 is an enlarged plan view of a dot on a TFT-array substrate of a liquid crystal apparatus according to an embodiment of the invention;

FIG. 3 is a cross-sectional view of the structure of a liquid crystal apparatus according to an embodiment of the invention;

FIGS. 4(a) to 4(c) are process drawings of a method for making a thin-film semiconductor device according to an embodiment of the invention;

FIGS. 5(a) to 5(c) are process drawings of a method for making a thin-film semiconductor device according to an embodiment of the invention;

FIGS. 6(a) to 6(c) are process drawings of a method for making a thin-film semiconductor device according to an embodiment of the invention;

FIGS. 7(a) to 7(c) are process drawings of a method for making a thin-film semiconductor device according to an embodiment of the invention;

FIGS. 8(a) and 8(b) are process drawings of a method for making a thin-film semiconductor device according to an embodiment of the invention;

FIG. 9(a) illustrates an embodiment of a cellular phone including a liquid crystal apparatus according to an embodiment of the invention;

FIG. 9(b) illustrates an embodiment of a portable information processor including a liquid crystal apparatus according to an embodiment of the invention;

FIG. 9(c) illustrates an embodiment of a watch-shaped electronic apparatus including a liquid crystal apparatus according to an embodiment of the invention;

FIGS. 10(a) to 10(d) illustrate a known technology in the technical field related to semiconductor devices such as an IC for controlling the LDD length; and

FIG. 11 is a cross-sectional view of a layered insulating film according to the invention showing the structure of the film immediately after it was formed.

### DETAILED DESCRIPTION OF PREFERRED EMBODIMENTS

Embodiments according to the invention are described below in detail.

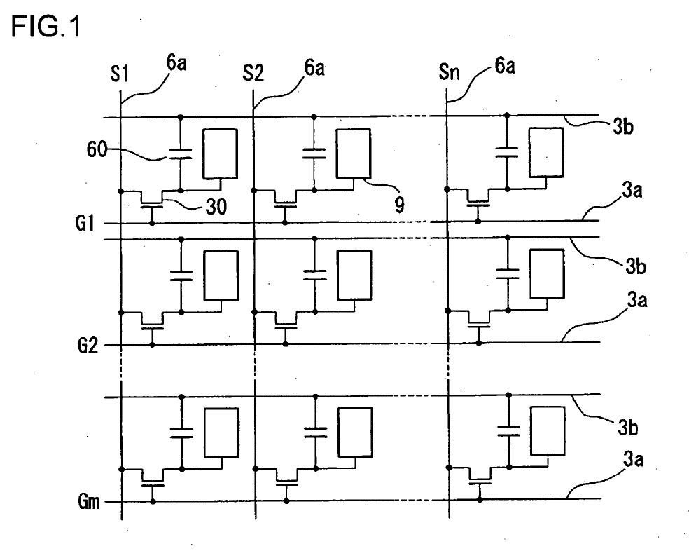

The structure of an electro-optic apparatus according to an embodiment of the invention is described by referring to FIGS. 1 to 3. This embodiment is an active-matrix transmissive liquid crystal apparatus having thin-film transistors (thin-film semiconductor device) as switching elements.

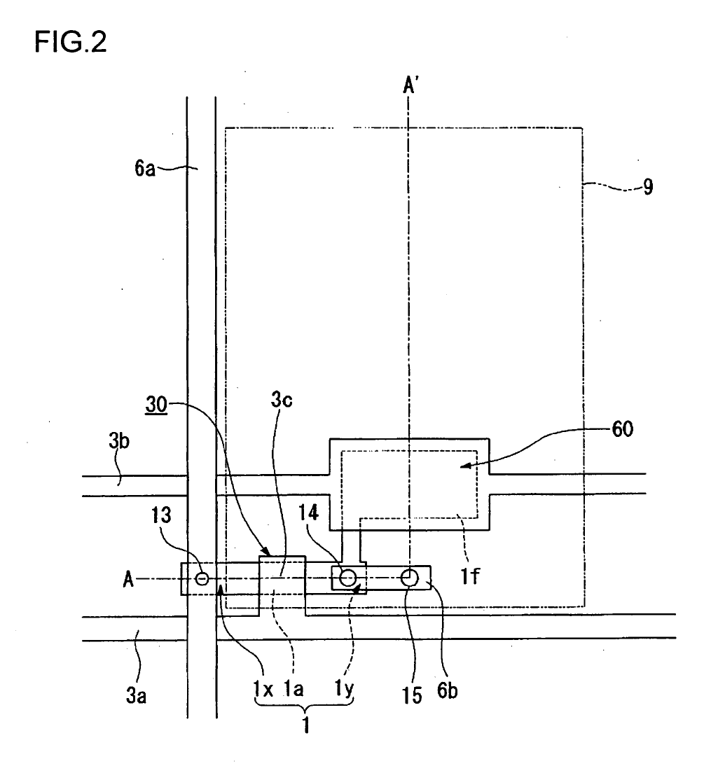

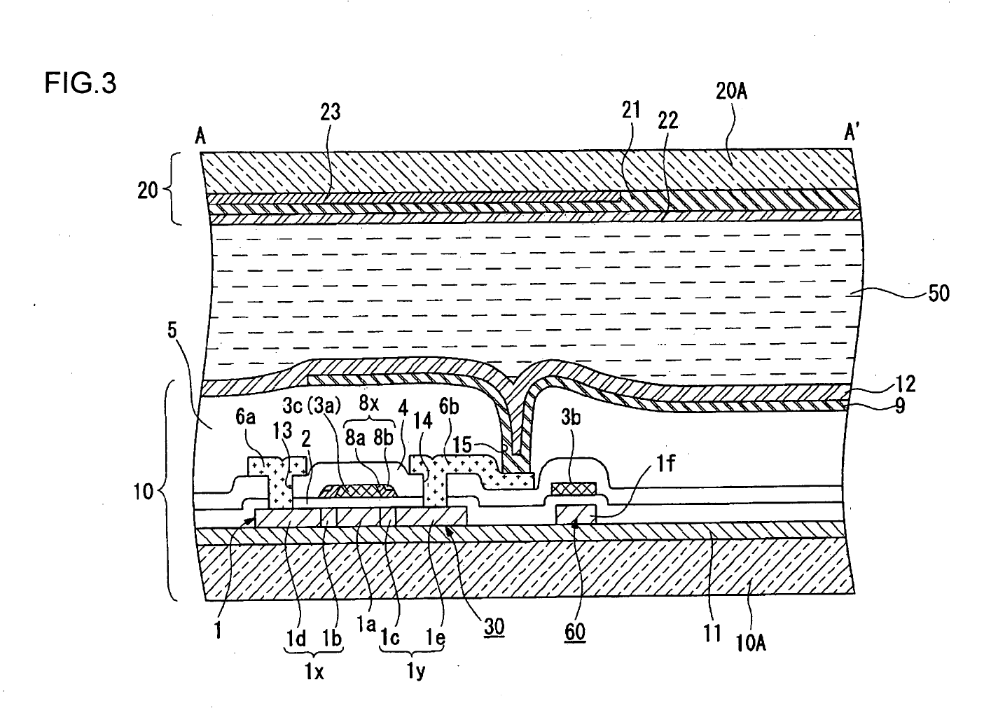

FIG. 1 is an equivalent circuit diagram of switching elements and signal lines for a plurality of dots arranged in a matrix constituting an image display area of a liquid crystal apparatus according to an embodiment of the present invention. FIG. 2 is an enlarged plan view of a dot on a TFT-array substrate with data lines, scanning lines, and pixel electrodes. FIG. 3 is a cross-sectional view taken along line A-A′ of FIG. 2 illustrating the structure of the liquid crystal apparatus according to an embodiment of the invention. In FIG. 3, light enters the upper portion of the drawing and an observer views the liquid crystal apparatus from the lower portion of the drawing. The thickness of each layer and the size of each part illustrated in the drawings are not presented to actual scale to make each layer and part easily viewable in the drawings.

As shown in FIG. 1, the dots arranged in a matrix composes the image display area of the liquid crystal apparatus according to this embodiment. Each dot has a pixel electrode 9 and a TFT (thin-film semiconductor) device 30, which is a switching element for controlling the pixel electrode 9. A data line 6a is electrically connected to a source of the TFT 30. Image signals S1, S2, . . . , Sn are line-sequentially input to the data line 6a in this order or input as a group to a plurality of adjacent data lines 6a.

A scanning line 3a is electrically connected to the gate of the TFT 30. Scanning signals G1, G2, . . . , Gm, which are pulsed signals, are line-sequentially input to a plurality of the scanning lines 3a at a predetermined timing. The pixel electrode 9 is electrically connected to a drain of the TFT 30. By turning on the TFT 30, which is a switching element, for a predetermined period of time, the image signals S1, S2, . . . , Sn from the data line 6a are input at a predetermined timing.

The image signals S1, S2, . . . , Sn input to the liquid crystal via the pixel electrode 9 are stored for a predetermined period of time, at a predetermined level between a common electrode as described below. The liquid crystal changes the orientation and order of its molecular association depending on the level of the voltage applied. In this way, the liquid crystal modulates light and enables gradation display. To prevent the stored image signals from leaking out, a storage capacitor 60 is connected in parallel with the liquid crystal interposed between the pixel electrode 9 and a common electrode.

As shown in FIG. 3, the liquid crystal apparatus according to this embodiment is composed of a liquid crystal layer 50, which is interposed between a TFT-array substrate 10 having a TFT 30 and a pixel electrode 9, and an opposing substrate 20 having a common electrode 21.

The planar structure of the TFT-array substrate 10 is described below by referring to FIG. 2.

The TFT-array substrate 10 has a plurality-of rectangular pixel electrodes 9 arranged in a matrix. As shown in FIG. 2, a data line 6a, a scanning line 3a and a storage line 3b are formed along the vertical and horizontal borders of each pixel electrode 9. In this embodiment, a dot is the area defined by the data line 6a and the scanning line 3a surrounding the pixel electrode 9.

The data line 6a is electrically connected to a source region 1x of a polycrystalline semiconductor film 1 composing the TFT 30 via a contact hole 13. The pixel electrode 9 is electrically connected to a drain region 1y of the polycrystalline semiconductor film 1, which makes up the TFT 30, via a contact hole 15, a source line 6b, and a contact hole 14. A part of the scanning line 3a is widened so that it opposes a channel region 1a of the polycrystalline semiconductor film 1. The widened part of the scanning line 3a functions as a gate electrode. In the following, the part of the scanning line 3a that functions as a gate electrode is referred to as the gate electrode and is indicated by the reference numeral 3c. The polycrystalline semiconductor film 1 composing the TFT 30 extends out to oppose the storage line 3b. This extended portion 1f and the storage line 3b function as a lower and upper electrode, respectively, to form a storage capacitor (storage capacitor element) 60.

Next, by referring to FIG. 3, the cross-sectional structure of the liquid crystal apparatus according to this embodiment is described.

The TFT-array substrate 10 is essentially composed of a substrate body (a transmissive substrate) 10A, a pixel electrode 9 formed near the surface of the liquid crystal layer 50, a TFT 30, and an alignment film 12. The opposing substrate 20 is essentially composed of a substrate body 20A formed of a transmissive material, such as glass, a common electrode 21 formed near the surface of the liquid crystal layer 50, and an alignment film 22.

More specifically, on the TFT-array substrate 10, a silicon oxide substrate protection film (buffering film) 11 is disposed directly on the substrate body 10A. Near the surface of the liquid crystal layer 50 of the substrate body 10A, a pixel electrode 9 composed of a transparent conductive material such as indium tin oxide (ITO) is disposed. A pixel-switching TFT 30 is disposed adjacent to the pixel electrode 9 to control the switching of the pixel electrode 9.

On the protective underlayer 11, polycrystalline semiconductor film 1 made of a polycrystalline silicon with a predetermined pattern is formed. On the polycrystalline semiconductor film 1, a silicon oxide gate-insulating film 2 is disposed. On the gate-insulating film 2, a scanning line 3a (gate electrode 3c) is formed. In this embodiment, the sides of the gate electrode 3c are tapered relative to the surface of the gate-insulating film 2. The part of the polycrystalline semiconductor film 1 opposing the gate electrode 3c with the gate-insulating film 2 interposed therebetween is a channel region 1a, where a channel is formed by the electrical field from the gate electrode 3c. On one side (left of the drawing) of the channel region 1a of the polycrystalline semiconductor film 1, a source region 1x is formed and, on the other side (right of the drawing) a drain region 1y is formed. Accordingly, the pixel-switching TFT 30 is composed of the gate electrode 3c, the gate-insulating film 2, the after-mentioned data line 6a and source line 6b, the source region 1x, the channel region 1a, and the drain region 1y of the polycrystalline semiconductor film 1.

In this embodiment, the pixel-switching TFT 30 has an LDD structure. The source region 1x and the drain region 1y are formed of high concentration regions (a high concentration source region and a high concentration drain region) with a relatively high concentration of impurity and low concentration regions (i.e., LDD regions (a low concentration source region and a low concentration drain region)) with a relatively low concentration of impurity. Hereinafter, the high concentration source region and the low concentration source region are indicated by the reference numerals 1d and 1b, respectively, and the high concentration drain region and the low concentration drain region are indicated by the reference numerals 1e and 1c, respectively.

On the gate electrode 3c disposed on the gate-insulating film 2, there is a first insulating film 8a with a width greater than the width of the gate electrode 3c disposed at least along the upper surface (the surface opposing the gate-insulating film) and the sides of the gate electrode 3c. On the first insulating film 8a, a second insulating film 8b is disposed. The areas of the source region 1x and the drain region 1y opposing the areas of the first insulating film 8a and the second insulating film 8b with a width greater than the width of the gate electrode 3c are the low concentration regions (LDD regions) 1b and 1c, respectively. The first and second insulating films 8a and 8b are formed of silicon nitride or silicon oxide. It is preferable to form the first insulating film 8a and the second insulating film 8b with different materials.

Hereinafter, a layered insulating film composed of a first and a second insulating film is indicated by the reference numeral 8x.

On the scanning line 3a (gate electrode 3c) formed on the substrate body 10A, a silicon oxide first interlayer insulating layer 4 is disposed. On this first interlayer insulating layer 4, the data line 6a and the source line 6b are formed. The data line 6a is electrically connected to the high concentration source region 1d of the polycrystalline semiconductor film 1 via the contact hole 13 formed on the first interlayer insulating layer 4. The source line 6b is electrically connected to the high concentration drain region 1e of the polycrystalline semiconductor film 1 via the contact hole 14 formed on the first interlayer insulating layer 4.

On the data line 6a and the source line 6b formed on the first interlayer insulating layer 4, a silicon nitride second interlayer insulating layer 5 is disposed. On the second interlayer insulating layer 5, the pixel electrode 9 is formed. The pixel electrode 9 is electrically connected to the source line 6b via the contact hole 15 formed on the second interlayer insulating layer 5.

The extended portion 1f (the lower electrode) extending from the high concentration drain region 1e of the polycrystalline semiconductor film 1 opposes the storage line 3b, which is the upper electrode on the same layer as the scanning line 3a, with an insulating layer (dielectric film) integrated with the gate insulating layer 2 interposed between the upper and lower electrodes. The extended portion 1f and the storage line 3b form a storage capacitor 60.

On the surface of the liquid crystal layer 50 of the TFT-array substrate 10, the alignment film 12 is disposed to control the alignment of the liquid crystal molecules inside the liquid crystal layer 50.

A light-blocking film 23 is disposed on the inner surface of the substrate body 20A of the opposing substrate 20 adjacent to the liquid crystal layer 50 to prevent the light that has entered into the liquid crystal apparatus from further reaching at least the channel region la and the low concentration regions 1b and 1c of the polycrystalline semiconductor film 1. The light-blocking film 23 disposed on the inner surface of the substrate body 20A is almost entirely covered with a common electrode 21 composed of ITO. An alignment film 22 for controlling the alignment of the liquid crystal molecules inside the liquid crystal layer 50 is interposed between the common electrode 21 and the liquid crystal layer 50.

The liquid crystal apparatus according to this embodiment can be structured as described above. This embodiment is characterized in that an insulating film 8x with a predetermined pattern is disposed at least along the upper surface and sides of the gate electrode 3c on the TFT 30.

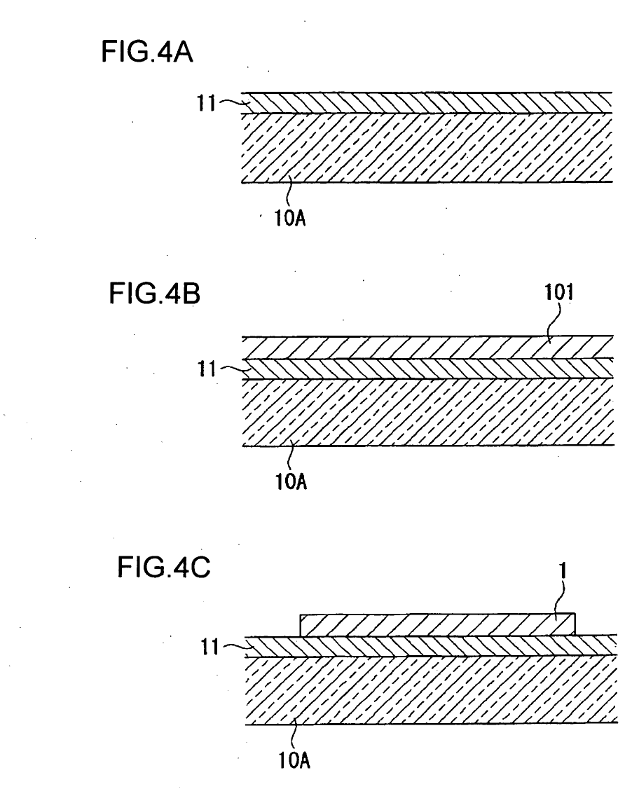

Subsequently, a method for making a TFT 30 (thin-film semiconductor device) disposed on a liquid crystal apparatus according to an embodiment of the invention is described by referring to FIGS. 4 to 8. An embodiment of an n-channel TFT is described. FIGS. 4 to 8 are all schematic cross-sectional views of the steps in the method for making the TFT according to this embodiment.

As shown in FIG. 4(A), a transmissive substrate such as a glass substrate cleaned by ultrasonic cleaning is prepared as a substrate body 10A. Then, under a condition in which the temperature of the substrate is 150 to 450° C., a silicon oxide substrate protection film (a buffering film) 11 with a thickness of 100 to 500 nm is disposed on the entire surface of the substrate body 10A by a plasma CVD method. As a source gas for this step, it is preferable to use a mixed gas of, for example, monosilane and dinitrogen monoxide, tetraethoxysilane (TEOS)(Si(OC₂H₅)₄) and oxygen, or disilane and ammonia.

Then, as shown in FIG. 4(B), under a condition in which the temperature of the substrate is 150 to 450° C., an amorphous silicon amorphous semiconductor film 101 with a thickness of 30 to 100 nm is disposed on the entire surface of the protective underlayer 11 on the substrate body 10A by a plasma CVD method. As a source gas for this step, it is preferable to use disilane or monosilane. Subsequently, as shown in FIG. 4(C), the amorphous semiconductor film 101 is laser annealed to form a polycrystalline silicon polycrystalline semiconductor film. This polycrystalline semiconductor film is photolithographically patterned to form an island-shaped polycrystalline semiconductor film 1.

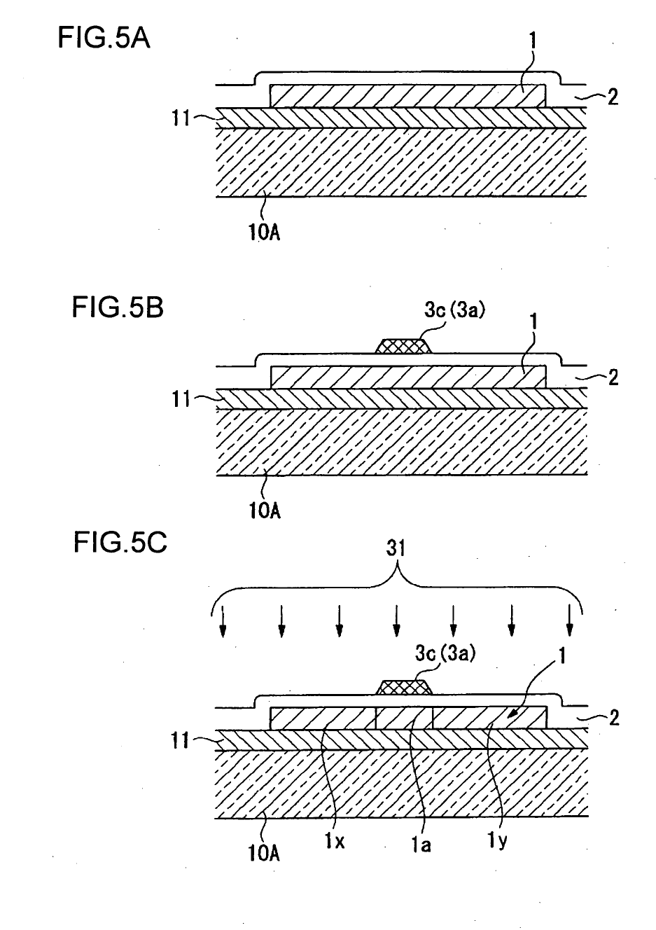

Then, as shown in FIG. 5(A), under a temperature of 350° C. or below, a silicon nitride gate-insulating film 2 with a thickness of 30 to 150 nm is disposed on the polycrystalline semiconductor film 1 on the substrate body 10A by a plasma CVD method. As a source gas for this step, it is preferable to use a mixed gas of TEOS and oxygen.

Then, as shown in FIG. 5(B), a conductive film formed of aluminum, tantalum, molybdenum, or a metal alloy mainly composed of one of these elements is disposed on the entire surface of the gate-insulating film 2 on the substrate body 10A by sputtering. Subsequently, a scanning line 3a (gate electrode 3c) with a thickness of 100 to 800 nm is formed by photolithographic patterning.

Next, as shown in FIG. 5(C), a low concentration of impurity ions (phosphorus ions) is implanted at a dose of about 0.1×10¹³ to 10×10¹³/cm² through the gate electrode 3c functioning as a mask. In this way, source region 1x and drain region 1y having a low concentration are formed in self-alignment with the gate electrode 3c. The part that is directly below the gate electrode 3c becomes a channel region 1a in which impurity ions were not implanted.

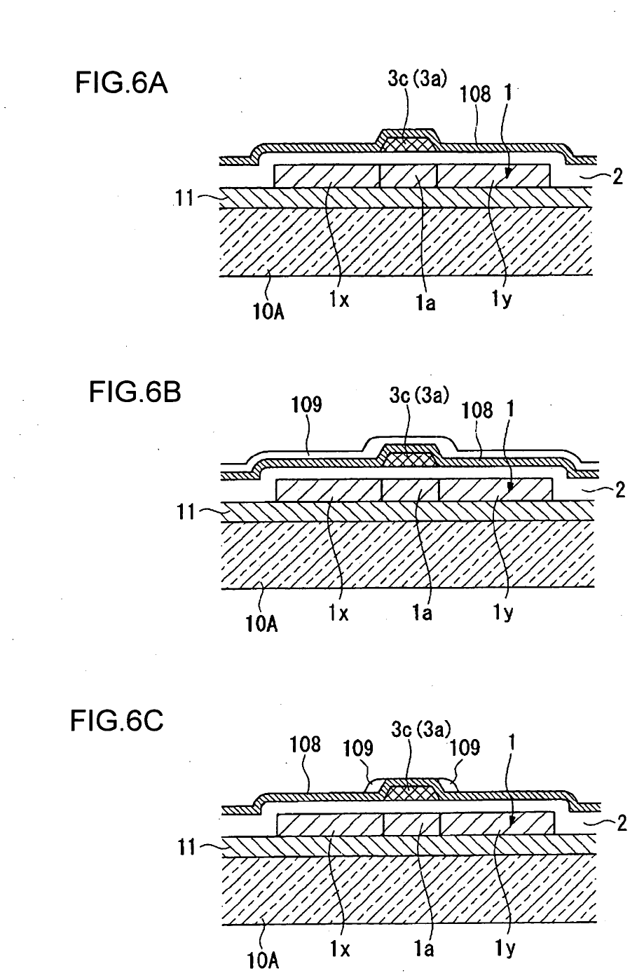

Then, as shown in FIG. 6(A), a first insulating film 108 with a thickness of 100 to 500 nm composed of silicon nitride or silicon oxide is disposed on the entire surface of the gate electrode 3c on the substrate body 10A by a CVD method. It is preferable to form the gate-insulating film 2 and the first insulating film 108 with different materials. Subsequently, as shown in FIG. 6(B), a second insulating film 109, which is different from the first insulating film 108, with a thickness of 100 nm to 1 μm is disposed on the first insulating film 108 by a CVD method. It is preferable for the thickness of the second insulating film 109 to be more than twice the thickness of the gate electrode 3c. In this way, a portion of the insulating film remains in the vicinity of the sides of the gate electrode 3c, and, thus, a long LDD length of 0.5 to 1.0 μm is achieved.

In this way, a layered insulating film for the sidewalls is formed on the surface of the gate electrode 3c and the gate-insulating film 2. In this formation process of the layered insulating film, it is preferable to compose the first insulating film 108 with an insulating material different from the gate-insulating film 2. For example, in this embodiment, the gate-insulating film 2 can be composed of silicon oxide and the first insulating film 108 is composed of silicon nitride. Furthermore, in this embodiment, the second insulating film 109 can be composed of silicon oxide so that the primary composition of the gate-insulating film 2 and the second insulating film 109 disposed on the lower and upper surfaces of the first insulating film 108, respectively, are the same composition.

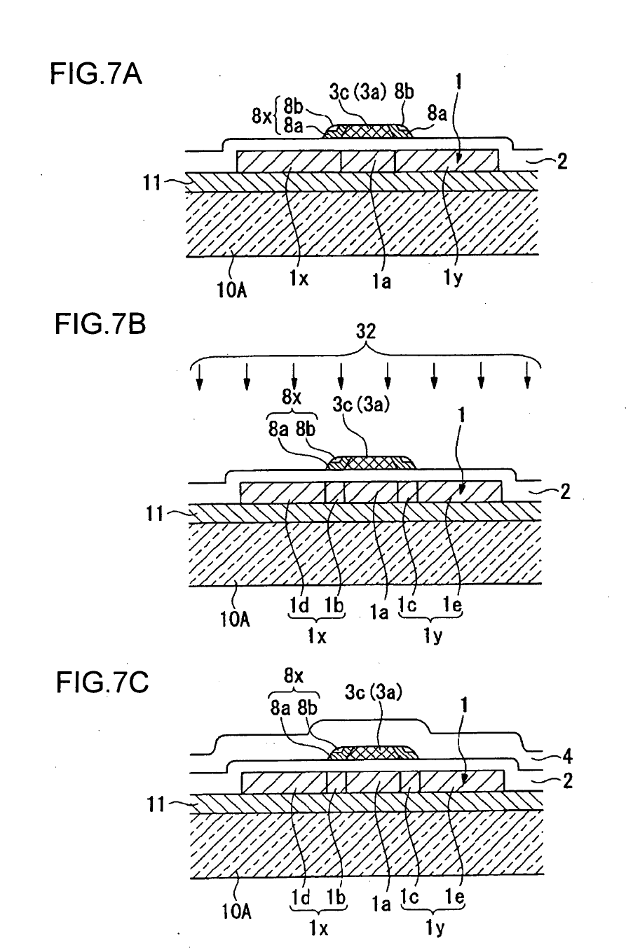

Next, as shown in FIGS. 6(C) and 7(A), by etching the entire surface of the layered insulating film composed of the first and second insulating films 108 and 109, the layered insulating film is processed according to a predetermined pattern having a width greater than the gate electrode 3c and smaller than the polycrystalline semiconductor film 1. In FIG. 7(A), the patterned insulating films 108 and 109 are indicated with the reference numerals 8a and 8b, respectively.

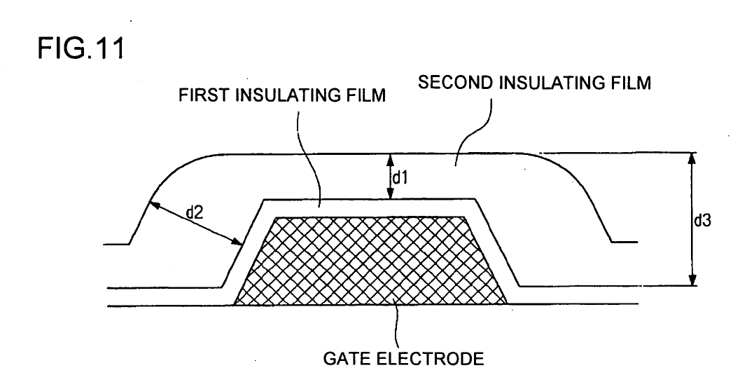

FIG. 11 is a cross-sectional view of the layered insulating film immediately after it is formed.

In this embodiment, at least the upper layer of the insulating film 109 is structured isotropically (i.e., d1=d2) or the horizontal parts are formed thicker than the upper part (i.e., d1<d2). Thus, the sides of the gate electrode 3c become thick (i.e., d1<d3). For this reason, when the entire layered insulating film is anisotropically etched (etched back), parts of the insulating film remain in the vicinity of the sides of the gate electrode 3c. Then, LDD regions are formed by doping an impurity, as described below, onto the parts corresponding to the remaining parts of the insulating film.

With this embodiment, when an insulating film for sidewalls is composed of a plurality of insulating films, a long LDD length of 0.5 to 1.0 μm for a tapered gate electrode can be achieved by controlling the conditions of the layers of the insulating film (film type, film thickness, and layered structure) and the conditions of etching.

For example, on a silicon oxide gate-insulating film 2, a silicon nitride first insulating film 108 and a silicon oxide second insulating film 109 are formed sequentially. Then, the entire surface is anisotropically etched so that the etching rate of the first insulating film 108 is slower than the etching rate of the second insulating film 109 (for instance, by using a carbon-rich fluorocarbon gas as a processing gas). In this etching process, first, overlaying the second insulating film 109 is removed. However, since the second insulating film 109 is thickly disposed in the vicinity of the gate electrode 3c, even when the second insulating film 109 around the gate electrode 3c is completely removed to expose the underlaying first insulating film 108, portions of the second insulating film 109 remain on the sides of the gate electrode 3c. The first insulating film 108 exposed in the vicinity of the gate electrode 3c is further etched. Since the etching rate of the first insulating film 108 is slower than the etching rate of the second insulating film 109 remaining on the sides of the gate electrode 3c, the etching of the first insulating film 108 in the vicinity of the gate electrode 3c develops slowly. In this way, the first insulating film 108 in the vicinity of the gate electrode 3c is patterned into a moderately tapered structure. As a result, by performing etching under the above-mentioned conditions, an insulating film with a greater width compared to the width of the insulating film that is remained when a single layer of the second insulating film is etched remains along the gate electrode 3c. Thus, performing etching in this manner is advantageous for forming an LDD region for a large-sized TFT.

In the etching process for the layered insulating film, the conditions for etching the overlaying second insulating film 109 and the conditions for etching the exposed underlaying first insulating film 108 may differ. For example, when etching the overlaying second insulating film 109, the etching rate of the overlaying second insulating film 109 may be faster than the etching rate of the underlaying first insulating film 108 (for instance, by using a carbon-rich fluorocarbon gas as a processing gas). On the other hand, when etching the exposed, underlaying first insulating film 108, the etching rate of the underlaying first insulating film 108 may be faster than the etching rate of the overlaying second insulating film 109 (for instance, by using a fluorogas including almost no carbon processing gas). In this way, the amount of etching performed on the gate-insulating film 2 is reduced as much as possible and a large amount of the second insulating film 109 is left in the vicinity of the gate electrode, allowing the LDD length to be longer than usual.

Since, in this embodiment, the first insulating film 8a and the gate-insulating film 2 are composed of different materials, the endpoint of the etching for the first insulating film 8a becomes apparent. As a result, there is no risk of overetching.

For example, the gate-insulating film 2, the first insulating film 108, and the second insulating film 109 are composed of silicon oxide, silicon nitride, and silicon oxide, respectively, and the entire surface of the layered film is anisotropically etched using a fluorocarbon (CF-based) gas. In this etching process, the oxygen included in the silicon oxide second insulating film 109 reacts with the carbon included in the fluorocarbon gas to produce carbon monoxide (CO) and carbon dioxide (CO₂). These gases are detectable by emission spectrometry or absorption spectrometry.

By analyzing the signal obtained through spectrometry, the endpoint of the etching for the second insulating film 109 can be detected. In other words, by etching the thinner portion of the film (the portion in the vicinity of the gate electrode) and exposing the silicon nitride first insulating film 108 (the step illustrated in FIG. 6(C)), the reactive oxygen is completely consumed and, thus, the intensity of the carbon monoxide or carbon dioxide signal detected by spectrometry is reduced. In this way, by controlling the etching according to the change in the signal, the volume and width of the insulating film 109 remaining in the vicinity of the gate electrode can be controlled. Consequently, the LDD length can be controlled. Furthermore, by detecting the endpoint of the etching of the first insulating film 108, which is the lower layer, by employing the same detecting method, the amount of etching performed on the gate electrode can be minimized.

As shown in FIG. 7(B), a high concentration of impurity ions (phosphorus ions) 32 is implanted at a dose of about 0.1×10¹⁵ to 10×10¹⁵/cm² through the insulating film 8x with a predetermined pattern functioning as a mask. In this way, in the source region 1x and the drain region 1y, high concentration regions 1d and 1e are formed, respectively, while the low concentration regions 1b and 1c remain directly under the insulating film 8x. More specifically, the low concentration regions (LDD regions) 1b and 1c are formed in the source region 1x and the drain region 1y, respectively, in self-alignment with the gate electrode 3c, wherein the low concentration regions (LDD regions) 1b and 1c have an LDD length substantially the same as the width of the insulating film 8x with a predetermined pattern but greater than the width of the gate electrode 3c.

As shown in FIG. 7(C), a silicon oxide first interlayer insulating layer 4 with a thickness of 300 to 800 nm is disposed on the entire surface of the insulating film 8x on the substrate body 10A. As a source gas for this step, it is preferable to use a mixed gas of, for example, TEOS and oxygen. Subsequently, the impurity implanted to the source regions 1x (high concentration source region 1d and low concentration source region 1b) and the drain regions 1y (high concentration drain region 1e and low concentration drain region 1c) are activated by laser annealing or furnace annealing.

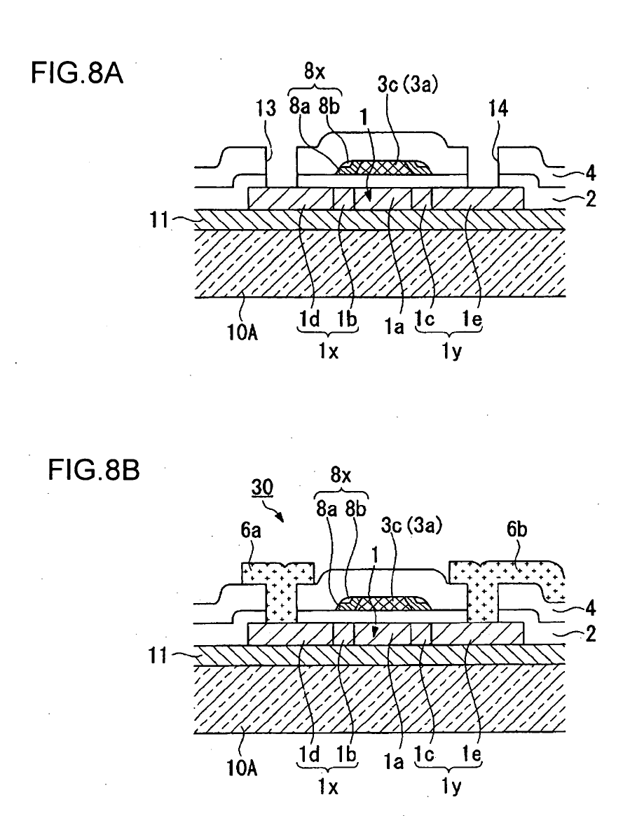

Next, as shown in FIG. 8(A), after disposing a photoresist (not depicted in the drawing) with a predetermined pattern, the first interlayer insulating layer 4 is dry-etched as the photoresist is used as a mask to form contact holes 13 and 14 on the high concentration source region 1d and high concentration drain region 1e, respectively.

Finally, as shown in FIG. 8(B), a metal film formed of aluminum, titanium, titanium nitride, tantalum, molybdenum, or a metal alloy mainly composed of one of these elements is disposed on the entire surface of the first interlayer insulating layer 4 by sputtering. Then a data line 6a and a source line 6b having a thickness of 400 to 800 nm are photolithographically patterned to produce an n-channel TFT 30.

As described in the above, in the method for making a TFT according to this embodiment, the low concentration source region 1x and drain region 1y are formed on the polycrystalline semiconductor film 1. Then, by controlling the conditions for etching the layered insulating film 8x composed of more than two different insulating films, a predetermined pattern with a width greater than the width of the gate electrode 3c and smaller than the width of the polycrystalline semiconductor film 1 is formed on the gate electrode 3c on the substrate body 10A. Using the layered insulating film 8x as a mask, a high concentration of impurity is implanted into the polycrystalline semiconductor film 1. In this way, the portions of the source region 1x and the drain region 1y that correspond to the portions of the layered insulating film 8x with a width greater than the width of the gate electrode 3c are equal to the LDD length. Consequently, the LDD length is long with a measurement of 0.5 μm to 1.0 μm.

The LDD length of the TFT 30 according to this embodiment produced in accordance with the above-mentioned method can be accurately controlled regardless of the structure of the sides of the gate electrode 3c and the LDD length. Hence, the performance of the TFT including durability and current-voltage characteristics becomes excellent.

In the above, only the method for making the TFT 30 was described. The liquid crystal apparatus according to this embodiment can be produced using known methods except that the TFT 30 is produced in accordance with the process described in the above. Therefore the processes for making the other parts of the liquid crystal apparatus are omitted.

For this embodiment, only a TFT having a polycrystalline silicon polycrystalline semiconductor film was described, but it should be understood that a TFT having a polycrystalline semiconductor film not composed of silicon may also be used. Furthermore, not only a TFT having a polycrystalline semiconductor film but also a TFT having an amorphous semiconductor film may be used. Moreover, for this embodiment, only an n-channel TFT was described, but, for the invention, a p-channel TFT may also be used. In this embodiment, a liquid crystal apparatus was described as an electro-optic apparatus. The invention, however, may be applied to any type of electro-optic apparatus including a TFT, such as an electroluminescence (EL) apparatus or a plasma display.

Embodiments of an electronic apparatus having a liquid crystal apparatus (electro-optic apparatus) according to the above-mentioned embodiments of the invention are described below.

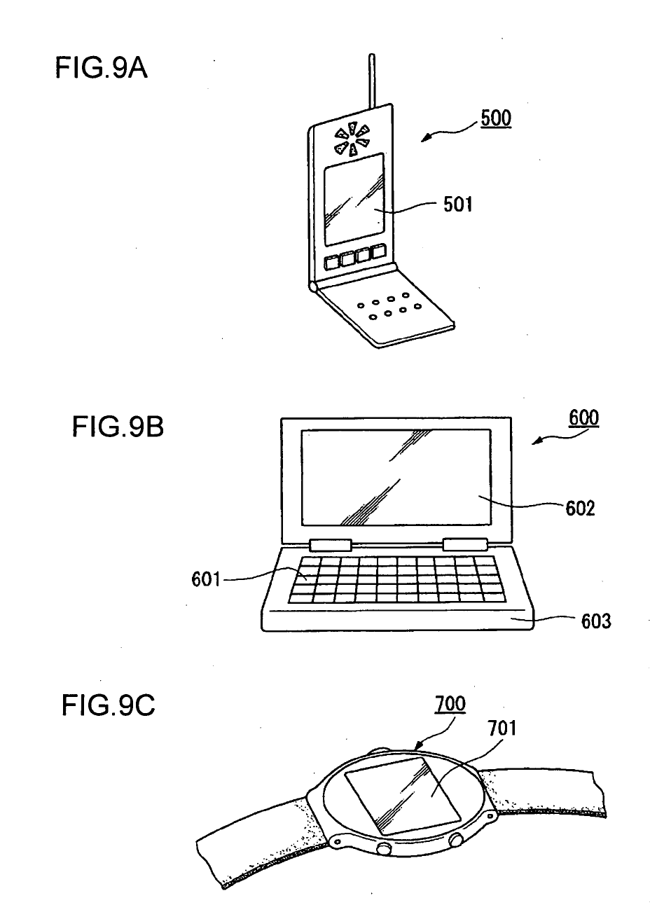

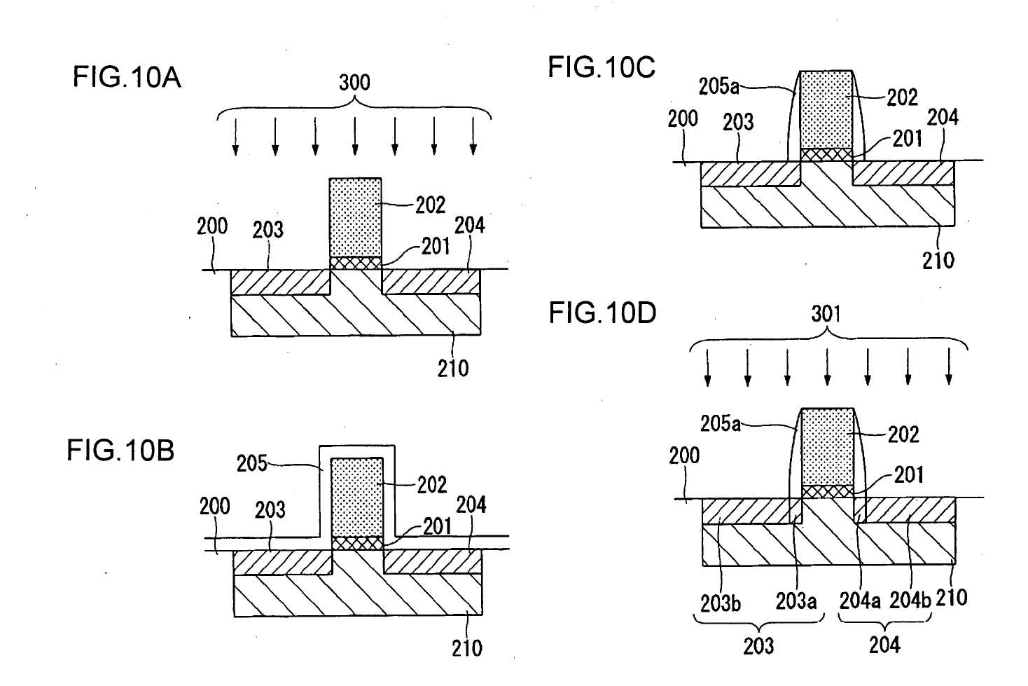

FIG. 9(A) is a perspective view of an embodiment of a cellular phone. In FIG. 9(a), the reference numeral 500 indicates a cellular phone and the reference numeral 501 indicates a liquid crystal display including the liquid crystal apparatus.

FIG. 9(B) is a perspective view of an embodiment of a portable information processor, such as a word processor or a personal computer. In FIG. 9(B), the reference numeral 600 indicates an information processor, the reference numeral 601 indicates an input unit such as a keyboard, the reference numeral 603 indicates an information processing body, and the reference numeral 602 indicates a liquid crystal display including the liquid crystal apparatus.

FIG. 9(C) is a perspective view of an embodiment of a watch-shaped electronic apparatus. In FIG. 9(C), the reference numeral 700 indicates the watch body, and the reference numeral 701 indicates a liquid crystal display including the liquid crystal apparatus.

The electronic apparatuses illustrated in FIGS. 9(A) to 9(C) include the liquid crystal apparatus according the above-mentioned embodiments, and, thus, these electronic apparatuses have excellent performance.

What is claimed is:

1. A method for making a thin-film semiconductor device including a semiconductor film having a source region, a channel region, and a drain region, a gate electrode opposing the semiconductor film and a gate-insulating film disposed between the semiconductor film and the gate electrode, the source region and the drain region further including a region with a relatively high impurity concentration and a region with a relatively low impurity concentration, respectively, the method including the steps of:
forming a semiconductor film with a predetermined pattern on a substrate;
forming a gate-insulating film on the semiconductor film;
forming a tapered gate electrode on the gate-insulating film;
implanting a low concentration of impurity into the semiconductor film through the gate electrode functioning as a mask;
forming a layer insulating film composed of at least two different insulating layers on the gate electrode on the substrate;
etching an entire surface of the layered insulating film to form a predetermined pattern in at least one of layer of the layered insulating film, the predetermined pattern having a width greater than a width of the gate electrode and smaller than a width of the semiconductor film; and
implanting a high concentration of impurity through the layered insulating film formed according to a predetermined pattern functioning as a mask.

2. The method for making a thin film semiconductor device according to claim 1, an uppermost layer of the layered insulating film being isotropically formed in the step of forming a layered insulating film and the entire surface of the layered insulating film being anisotropically etched in the step of etching the layered insulating film.

3. The method for making a thin film semiconductor device according to claim 2, anisotropic etching being performed after forming a predetermined pattern in at least one of the layers of the layered insulating film, the predetermined pattern having a width greater than the width of the gate electrode and smaller than the width of the semiconductor film.

4. The method for making a thin film semiconductor device according to claim 1, an uppermost insulating layer of the layered insulating film and the gate-insulating film having substantially a same composition.

5. The method for making a thin film semiconductor device according to claim 1, an endpoint of etching for an uppermost insulating layer of the layered insulating film controls a volume of the insulating film remaining in a vicinity of the gate electrode being controlled in the step of etching the layered insulating film.

6. The method for making a thin film semiconductor device according to claim 1, an etching rate of an upper insulating layer being greater than an etching rate of a lower insulating layer and an etching rate of the exposed lower insulating layer being greater than an etching rate of the upper insulating layer in the step of etching the layered insulating film.

7. The method for making a thin film semiconductor device according to claim 1, the gate-insulating film being composed of silicon oxide.

8. The method for making a thin film semiconductor device according to claim 7, the layered insulating film further comprising a first insulating layer composed of silicon nitride and a second insulating layer composed of silicon oxide on the first insulating film.

9. A thin film semiconductor device made by the method for making a thin film semiconductor device according to claim 1,
the insulating film being formed at least along sides of the gate electrode, and each of the source region and the drain region of the semiconductor having a low concentration region corresponding to a portion of the insulating film with a width greater than the gate electrode.

10. A method for making an electro-optic apparatus having a thin-film semiconductor device including a semiconductor film having a source region, a channel region, and a drain region, a gate electrode opposing the semiconductor film, and a gate-insulating film disposed between the semiconductor film and the gate electrode, the source region and the drain region including a region with a relatively high impurity concentration and a region with a relatively low impurity concentration, respectively, the method comprising the steps of:
forming a semiconductor film with a predetermined pattern on a substrate;
forming a gate-insulating film on the semiconductor film;
forming a tapered gate electrode on the gate-insulating film;
implanting a low concentration of impurity into the semiconductor film through the gate electrode functioning as a mask;
forming a layered insulating film composed of at least two different insulating layers on gate electrode on the substrate;
etching an entire surface of the layered insulating film to form a predetermined pattern in at least one of the layers of the layered insulating film, the predetermined pattern having a width greater than the width of the gate electrode and smaller than the width of the semiconductor film; and
implanting a high concentration of impurity into the semiconductor film through the layered insulating film formed according to a predetermined pattern functioning as a mask.

11. An electro-optic apparatus made by the method according to claim 10, the insulating film being formed at least along sides of the gate electrode, and each of the source region and the drain region of the semiconductor film having a low concentration region corresponding to the portion of the layered insulating film with a width greater than the gate electrode.

12. An electronic apparatus including the electro-optic apparatus according to claim 11.
